(19) United States
(12) Patent Application Publication
(10) Pub. No.: US 2025/0297141 A1
(43) Pub. Date: Sep. 25, 2025

(54) ADHESIVE COMPOSITION, ADHESIVE, ADHESIVE SHEET, DISPLAY BODY, AND REPEATED BENDING DEVICE

(71) Applicant: LINTEC CORPORATION, Tokyo (JP)

(72) Inventors: Sho KOSABA, Tokyo (JP); Takayuki ARAI, Tokyo (JP); Mikihiro KASHIO, Tokyo (JP)

(73) Assignee: LINTEC CORPORATION, Tokyo (JP)

(21) Appl. No.: 18/866,229

(22) PCT Filed: Apr. 26, 2023
(86) PCT No.: PCT/JP2023/016418

§ 371 Date: Nov. 15, 2024

(30) Foreign Application Priority Data
May 17, 2022 (JP) 2022-080997

(51) Int. Cl. C09J 7/38; C09J 105/16; C09J 133/08; C09J 133/10; H10K 59/80; H10K 102/00

(52) U.S. Cl. CPC C09J 7/385; C09J 105/16; C09J 133/08; C09J 133/10; H10K 59/8722; C09J 2301/302; H10K 2102/311

(57) ABSTRACT

A pressure sensitive adhesive composition containing a multimer of modified cyclodextrin; a pressure sensitive adhesive obtained from the pressure sensitive adhesive composition; and a pressure sensitive adhesive sheet having a pressure sensitive adhesive layer formed of the pressure sensitive adhesive. The multimer of modified cyclodextrin is preferably a dimer. The pressure sensitive adhesive is preferably an acrylic-based pressure sensitive adhesive and, in particular, preferably contains a crosslinked product obtained by crosslinking a (meth)acrylic ester polymer using a crosslinker.

### TECHNICAL FIELD

The present invention relates to a pressure sensitive adhesive composition, a pressure sensitive adhesive, a pressure sensitive adhesive sheet, a display body, a repetitive bending laminate member, and a repetitive bending device.

### BACKGROUND ART

Pressure sensitive adhesives (also referred to as pressure sensitive adhesive glues) are processed, for example, into tapes, labels, etc., and are used in a wide range of applications. There are also a wide variety of objects to which pressure sensitive adhesives can be applied, and they are applied to various materials, including plastics, paper, metals, glass, and pottery.

Also in various devices, for example, in display bodies (displays) of electronic devices, their members are often bonded together using pressure sensitive adhesives. In recent years, bendable displays that can be bent have been proposed as a type of displays. Proposed bendable displays include those formed in a curved shape only once as well as repetitive bending displays for being repeatedly bent (folded).

For such a repetitive bending display as described above, it is conceivable to bond one member (bendable member) that is bendable and constitutes the bendable display to another bendable member via the pressure sensitive adhesive layer of a pressure sensitive adhesive sheet. Unfortunately, however, if the conventional pressure sensitive adhesive sheet is used for a repetitive bending display, the repeated bending may cause problems in durability, such as the occurrence of delamination at the interface between the pressure sensitive adhesive layer and an adherend in the bending portion.

Patent Document 1 discloses a pressure sensitive adhesive for the purpose of suppressing the occurrence of delamination during repeated bending, etc.

### PRIOR ART DOCUMENTS

### Patent Documents

[Patent Document 1] WO2019/026753

### SUMMARY OF THE INVENTION

### Problems to be Solved by the Invention

Here, in order to make a pressure sensitive adhesive resistant to repeated bending, it is conceivable to make the pressure sensitive adhesive low elastic. If, however, the cohesive strength is reduced to make the pressure sensitive adhesive low elastic, the reworkability will deteriorate, and the pressure sensitive adhesive may readily remain on the adherend from which the pressure sensitive adhesive sheet has been released. On the other hand, if the pressure sensitive adhesive layer is made harder by increasing the amount of crosslinker in order to improve the reworkability, the pressure sensitive adhesive properties will deteriorate, and the repetitive bending ability will also be poor.

The present invention has been made in view of such actual circumstances as describe above, and objects of the present invention include providing a pressure sensitive adhesive composition, a pressure sensitive adhesive, and a pressure sensitive adhesive sheet that allow both the pressure sensitive adhesive properties and the reworkability to be achieved, and also providing a display body, a repetitive bending laminate member, and a repetitive bending device that are obtained using them.

### Means for Solving the Problems

To achieve the above objects, first, the present invention provides a pressure sensitive adhesive composition containing a multimer of modified cyclodextrin (Invention 1).

The pressure sensitive adhesive obtained from the pressure sensitive adhesive composition according to the above invention (Invention 1) contains a multimer of modified cyclodextrin and can thereby obtain high cohesive strength while maintaining low elasticity and interfacial adhesion to an adherend. This allows both the pressure sensitive adhesive properties and the reworkability to be achieved. Moreover, the above pressure sensitive adhesive has excellent optical properties, and the display body obtained using the above pressure sensitive adhesive is therefore excellent in the image visibility from an oblique angle in addition to the image visibility from the front. Furthermore, in the repetitive bending laminate member and the repetitive bending device that are obtained using the above pressure sensitive adhesive, due to the excellent pressure sensitive adhesive properties (including the property of low elasticity) of the pressure sensitive adhesive, even when they are repeatedly bent, floating or delamination is unlikely to occur at the interface between the pressure sensitive adhesive layer and the adherend at the bent portion, and the bending resistance is excellent.

In the above invention (Invention 1), the multimer of modified cyclodextrin may be preferably a dimer (Invention 2).

Second, the present invention provides a pressure sensitive adhesive obtained from the pressure sensitive adhesive composition (Invention or Inventions 1 and 2) (Invention 3)

The pressure sensitive adhesive according to the above invention (Invention 3) may be preferably an acrylic-based pressure sensitive adhesive (Invention 4).

The pressure sensitive adhesive according to the above invention or inventions (Invention or Inventions 3 and 4) may preferably contain a crosslinked product obtained by crosslinking a (meth)acrylic ester polymer with a crosslinker (Invention 5).

The pressure sensitive adhesive according to the above invention or inventions (Invention or Inventions 3 to 5) may preferably have a 100% modulus of 0.13 N/mm² or less (Invention 6)

The pressure sensitive adhesive according to the above invention or inventions (Invention or Inventions 3 to 6) may preferably have a breaking stress in a tensile test of 0.25 N/mm² or more (Invention 7).

The pressure sensitive adhesive according to the above invention or inventions (Invention or Inventions 3 to 7) may preferably have a breaking elongation in a tensile test of 650% or more (Invention 8).

The pressure sensitive adhesive according to the above invention or inventions (Invention or Inventions 3 to 8) may be preferably a pressure sensitive adhesive for bonding an optical member and another optical member (Invention 9).

The pressure sensitive adhesive according to the above invention or inventions (Invention or Inventions 3 to 9) may be preferably a pressure sensitive adhesive for bonding a bendable member and another bendable member that constitute a device that is repeatedly bent (Invention 10).

Third, the present invention provides a pressure sensitive adhesive sheet having at least a pressure sensitive adhesive layer, wherein the pressure sensitive adhesive layer comprises the pressure sensitive adhesive (Invention or Inventions 3 to 10) (Invention 11).

In the above invention (Invention 11), the adhesive strength to non-alkali glass may be preferably 1.0 N/25 mm or more and 50 N/25 mm or less (Invention 12).

In the above invention or inventions (Invention or Invention 11 and 12), the pressure sensitive adhesive sheet may preferably include two release sheets, and the pressure sensitive adhesive layer may be preferably interposed between the two release sheets so as to be in contact with release surfaces of the two release sheets (Invention 13).

Fourth, the present invention provides a display body comprising: a first display body structural member; a second display body structural member; and a pressure sensitive adhesive layer that bonds the first display body structural member and the second display body structural member to each other, wherein the pressure sensitive adhesive layer is formed of the pressure sensitive adhesive (Invention or Inventions 3 to 10) (Invention 14).

Fifth, the present invention provides a repetitive bending laminate member comprising: a bendable member and another bendable member that constitute a device that is repeatedly bent; and a pressure sensitive adhesive layer that bonds the bendable member and the other bendable member to each other, wherein the pressure sensitive adhesive layer is formed of the pressure sensitive adhesive (Invention or Inventions 3 to 10) (Invention 15).

Sixth, the present invention provides a repetitive bending device comprising the repetitive bending laminate member (Invention 15) (Invention 16).

### Advantageous Effect of the Invention

According to the pressure sensitive adhesive composition, pressure sensitive adhesive, and pressure sensitive adhesive sheet of the present invention, both the pressure sensitive adhesive properties and the reworkability can be achieved. Moreover, the display body according to the present invention is excellent in the image visibility from the front and from an oblique angle. Furthermore, the repetitive bending laminate member and repetitive bending device according to the present invention are excellent the bending resistance.

### BRIEF DESCRIPTION OF DRAWINGS

FIG. 1 is a cross-sectional view of a pressure sensitive adhesive sheet according to an embodiment of the present invention.

FIG. 2 is a cross-sectional view of a repetitive bending laminate member according to an embodiment of the present invention.

FIG. 3 is a cross-sectional view of a repetitive bending device according to an embodiment of the present invention.

FIG. 4 is an explanatory diagram (side view) for describing the bending test.

### EMBODIMENTS FOR CARRYING OUT THE INVENTION

One or more embodiments of the present invention will be described below.

### <Pressure Sensitive Adhesive Composition>

The pressure sensitive adhesive composition according to an embodiment of the present invention contains a multimer of modified cyclodextrin (which may be referred to as a “modified cyclodextrin multimer,” hereinafter). As used in the present specification, the term “modified” in the modified cyclodextrin means that at least some of the hydroxyl groups of cyclodextrin are substituted with other functional groups or are bonded to another compound by a reaction. The “multimer” in the present specification refers to one having a skeleton of dimer or more.

The pressure sensitive adhesive obtained from the pressure sensitive adhesive composition according to the present embodiment contains a multimer of modified cyclodextrin and can thereby obtain high cohesive strength while maintaining low elasticity and interfacial adhesion to an adherend. This allows the above pressure sensitive adhesive to achieve both the pressure sensitive adhesive properties and the reworkability. Moreover, the pressure sensitive adhesive obtained from the pressure sensitive adhesive composition according to the present embodiment has excellent optical properties. The display body obtained using the above pressure sensitive adhesive is therefore excellent in the image visibility from an oblique angle in addition to the image visibility from the front. Furthermore, in the repetitive bending laminate member and the repetitive bending device that are obtained using the above pressure sensitive adhesive, due to the excellent pressure sensitive adhesive properties (including the property of low elasticity) of the pressure sensitive adhesive, even when they are repeatedly bent, floating or delamination is unlikely to occur at the interface between the pressure sensitive adhesive layer and the adherend at the bent portion, and the bending resistance is excellent.

In general, cyclodextrins having 5 or more glucose constitutional units are known. The cyclodextrin serving as the skeleton of the modified cyclodextrin in the present embodiment may be cyclodextrin having 5 glucose constitutional units, α-cyclodextrin having 6 glucose constitutional units, β-cyclodextrin having 7 glucose constitutional units, or γ-cyclodextrin having 8 glucose constitutional units. Among them, the modified cyclodextrin in the present embodiment may be preferably at least one of those obtained by modifying β-cyclodextrin (modified β-cyclodextrin) and modifying γ-cyclodextrin (modified γ-cyclodextrin) from the viewpoint of readily imparting better pressure sensitive adhesive properties and reworkability, and modified β-cyclodextrin may be particularly preferred.

The substituent or compound that modifies the modified cyclodextrin in the present embodiment may be preferably one that can multimerize the modified cyclodextrin. Examples of the above substituent include an isocyanate group, a carboxyl group, an amino group, a thiol group, a vinyl group, an azide group, and an alkynyl group. The above substituent can be preliminarily introduced into cyclodextrin, and the cyclodextrin can be multimerized using the substituent. Examples of the above compound include poly(alkylene glycol) tolylene-2,4-diisocyanate, poly(alkylene glycol) tolylene-2,6-diisocyanate, poly(alkylene glycol) xylylene-2,4-diisocyanate, poly(alkylene glycol) xylylene-2,6-diisocyanate, hexamethylene diisocyanate, isophorone diisocyanate, tolylene diisocyanate, xylylene diisocyanate, and methylenebis(4,1-phenylene) diisocyanate. The alkylene glycol portion in the above compounds may be preferably ethylene glycol or propylene glycol and particularly preferably propylene glycol. The number of repeating units of the above alkylene glycol portion may be preferably 1 to 100, more preferably 6 to 80, particularly preferably 12 to 60, and further preferably 18 to 40. Among the above, poly(alkylene glycol)tolylene-2,4-diisocyanate may be preferred and poly(propylene glycol)tolylene-2,4-diisocyanate may be particularly preferred from the viewpoints of the pressure sensitive adhesive properties and reworkability of the obtained pressure sensitive adhesive and the ease of producing the multimer of modified cyclodextrin.

The degree of modification of the modified cyclodextrin in the present embodiment may be preferably 1.0 to 3.0, particularly preferably 2.0 to 3.0, and further preferably 3.0. This allows the obtained pressure sensitive adhesive to have better pressure sensitive adhesive properties and reworkability, and the multimer of modified cyclodextrin can be easily produced. As used in the present specification, the degree of modification of the modified cyclodextrin is the number of modified hydroxyl groups per one glucose constitutional unit. Therefore, if three hydroxyl groups in one glucose constitutional unit are all substituted, the degree of modification is 3.0.

The modified cyclodextrin multimer in the present embodiment may be preferably a dimer to a pentamer, more preferably a dimer to a tetramer, particularly preferably a dimer to a trimer, and further preferably a dimer. This allows the modified cyclodextrin multimer to be more soluble in a solvent, and the pressure sensitive adhesive properties and reworkability of the obtained pressure sensitive adhesive can be more excellent. The pressure sensitive adhesive composition according to the present embodiment may contain modified cyclodextrin multimers with different numbers of repeating skeletons.

The molecular weight (number-average molecular weight: Mn) of the modified cyclodextrin multimer in the present embodiment may be preferably 1,800 to 20,000, more preferably 2,000 to 15,000, particularly preferably 2,300 to 12,000, and further preferably 2,500 to 10,000. This allows the obtained pressure sensitive adhesive to be more excellent in the pressure sensitive adhesive properties and reworkability.

The modified cyclodextrin multimer in the present embodiment can be preferably prepared by reacting cyclodextrin with a compound having a modifying functional group or with a modifying compound. These compounds usually have functional groups that are highly reactive with the hydroxyl groups possessed by cyclodextrin, such as isocyanate groups, carboxyl groups, and amino groups.

The content of the modified cyclodextrin multimer in the pressure sensitive adhesive composition according to the present embodiment may be preferably 0.1 to 50 mass %, more preferably 0.5 to 30 mass %, particularly preferably 1 to 20 mass %, further preferably 3 to 15 mass %, and most preferably 6 to 12 mass %. This allows the obtained pressure sensitive adhesive to have better pressure sensitive adhesive properties and reworkability.

Examples of the types of the pressure sensitive adhesive in the present embodiment include an acrylic-based pressure sensitive adhesive, a polyester-based pressure sensitive adhesive, a polyurethane-based pressure sensitive adhesive, a rubber-based pressure sensitive adhesive, and a silicone-based pressure sensitive adhesive. The pressure sensitive adhesive may be any of emulsion type, solvent type, or non-solvent type and may also be crosslinked type or non-crosslinked type. Among these, acrylic-based pressure sensitive adhesives may be preferred because they are excellent in the pressure sensitive adhesive physical properties, optical properties, etc. As the acrylic-based pressure sensitive adhesives, crosslinking type ones may be preferred, and thermal crosslinking type ones may be further preferred. The pressure sensitive adhesive may also be non-curable with active energy rays or curable with active energy rays.

Specifically, the pressure sensitive adhesive composition according to the present embodiment may be preferably a pressure sensitive adhesive composition that contains a (meth)acrylic ester polymer (A) and a modified cyclodextrin multimer (B) and optionally further contains a crosslinker (C), a silane coupling agent (D), etc. (this pressure sensitive adhesive composition may be referred to as a “pressure sensitive adhesive composition P,” hereinafter). This allows the obtained pressure sensitive adhesive to have better pressure sensitive adhesive properties and reworkability. As used in the present specification, the term “(meth)acrylic acid” refers to both the acrylic acid and the methacrylic acid. The same applies to other similar terms. As used in the present specification, the term “polymer” encompasses the concept of a “copolymer.”

### (1) Components of Pressure Sensitive Adhesive Composition P

### (1-1) (Meth)Acrylic Ester Polymer (A)

The (meth)acrylic ester polymer (A) in the present embodiment may preferably contain, as a monomer unit that constitutes the polymer, a reactive group-containing monomer having a reactive group in the molecule. This allows the modified cyclodextrin multimer (B) to be uniformly present in the pressure sensitive adhesive, and the obtained pressure sensitive adhesive can exhibit favorable adhesive strength and reworkability. When the pressure sensitive adhesive composition P contains the crosslinker (C), the reactive group derived from the above reactive group-containing monomer reacts with the crosslinker (C) thereby to form a crosslinked structure (three-dimensional network structure) Such a pressure sensitive adhesive is more likely to develop the desired cohesive strength and can have more favorable pressure sensitive adhesive properties and reworkability.

Preferred examples of the above reactive group-containing monomer include a monomer having a hydroxyl group in the molecule (hydroxyl group-containing monomer), a monomer having a carboxy group in the molecule (carboxy group-containing monomer), and a monomer having an amino group in the molecule (amino group-containing monomer). Among them, it may be preferred to use a hydroxyl group-containing monomer or a carboxy group-containing monomer, and it may also be preferred to use a hydroxyl group-containing monomer and a carboxy group-containing monomer in combination.

Examples of the hydroxyl group-containing monomer include hydroxyalkyl (meth)acrylates such as 2-hydroxyethyl (meth)acrylate, 2-hydroxypropyl (meth)acrylate, 3-hydroxypropyl (meth)acrylate, 2-hydroxybutyl (meth)acrylate, 3-hydroxybutyl (meth)acrylate, and 4-hydroxybutyl (meth)acrylate. Among these, hydroxyalkyl (meth)acrylates having a hydroxyalkyl group whose carbon number is 1 to 4 may be preferred from the viewpoints of the reactivity of the hydroxyl group in the obtained (meth)acrylic ester polymer (A) with the crosslinker (C) and the copolymerizability with other monomers. Specifically, for example, 2-hydroxyethyl (meth)acrylate, 4-hydroxybutyl (meth)acrylate, or the like may be preferred, and 2-hydroxyethyl acrylate or 4-hydroxybutyl acrylate may be particularly preferred. These may each be used alone or two or more types may also be used in combination.

Examples of the carboxy group-containing monomer include ethylenically unsaturated carboxylic acids such as acrylic acid, methacrylic acid, crotonic acid, maleic acid, itaconic acid, and citraconic acid. Among these, acrylic acid may be preferred from the viewpoints of the reactivity of the carboxy group in the obtained (meth)acrylic ester polymer (A) with the crosslinker (C) and the copolymerizability with other monomers. These may each be used alone or two or more types may also be used in combination.

Examples of the amino group-containing monomer include aminoethyl (meth)acrylate and n-butylaminoethyl (meth)acrylate. These may each be used alone or two or more types may also be used in combination. Nitrogen atom-containing monomers, which will be described later, are excluded from the amino group-containing monomers.

The (meth)acrylic ester polymer (A) may preferably contain 0.01 to 50 mass %, more preferably 0.1 to 35 mass %, particularly preferably 1 to 20 mass %, further preferably 3 to 15 mass %, and most preferably 5 to 10 mass % of the reactive group-containing monomer as a monomer unit that constitutes the polymer. This allows a good crosslinked structure to be formed in the obtained pressure sensitive adhesive, which is more likely to develop the desired cohesive strength and can have more favorable pressure sensitive adhesive properties and reworkability.

The (meth)acrylic ester polymer (A) may also preferably contain (meth)acrylic alkyl ester as a monomer unit that constitutes the polymer. This can readily develop good pressure sensitive adhesive properties. The alkyl group in the (meth)acrylic alkyl ester may be linear or branched.

From the viewpoint of the pressure sensitive adhesive properties, (meth)acrylic alkyl ester whose carbon number of alkyl group is 1 to 20 may be preferred as the (meth)acrylic alkyl ester. Examples of the (meth)acrylic alkyl ester whose carbon number of alkyl group is 1 to 20 include methyl (meth)acrylate, ethyl (meth)acrylate, propyl (meth)acrylate, n-butyl (meth)acrylate, n-pentyl (meth)acrylate, n-hexyl (meth)acrylate, 2-ethylhexyl (meth)acrylate, isooctyl (meth)acrylate, n-decyl (meth)acrylate, n-dodecyl (meth)acrylate, myristyl (meth)acrylate, palmityl (meth)acrylate, and stearyl (meth)acrylate. Among these, from the viewpoint of more improving the pressure sensitive adhesive properties, (meth)acrylic ester whose carbon number of alkyl group is 4 to 10 may be preferred, and (meth)acrylic ester whose carbon number of alkyl group is 4 to 8 may be particularly preferred. Specifically, n-butyl (meth)acrylate, 2-ethylhexyl (meth)acrylate, etc. may be preferred, and n-butyl acrylate or 2-ethylhexyl acrylate may be particularly preferred. These may each be used alone or two or more types may also be used in combination.

The (meth)acrylic ester polymer (A) may preferably contain 50 to 99.99 mass %, more preferably 65 to 99.9 mass %, particularly preferably 80 to 99 mass %, further preferably 85 to 97 mass %, and most preferably 90 to 95 mass % of the (meth)acrylic alkyl ester as a monomer unit that constitutes the polymer. This allows the obtained pressure sensitive adhesive to be more excellent in the pressure sensitive adhesive properties. Moreover, a desired amount of other monomers such as a reactive functional group-containing monomer can be readily introduced into the (meth)acrylic ester polymer (A)

If desired, the (meth)acrylic ester polymer (A) may contain other monomers as monomer units that constitute the polymer. Examples of such monomers include a monomer having an alicyclic structure in the molecule (alicyclic structure-containing monomer), a monomer having an aromatic ring in the molecule (aromatic ring-containing monomer), a non-reactive nitrogen atom-containing monomer such as N-acryloyl morpholine or N-vinyl-2-pyrrolidone, alkoxyalkyl (meth)acrylates such as methoxyethyl (meth)acrylate and ethoxyethyl (meth)acrylate, vinyl acetate, and styrene. These may each be used alone or two or more types may also be used in combination.

The (meth)acrylic ester polymer (A) may be preferably a linear polymer. Such a linear polymer may promote the entanglement of molecular chains, and improvement in the cohesive strength can be expected.

The (meth)acrylic ester polymer (A) may be preferably a solution polymerization product obtained by a solution polymerization method. Being a solution polymerization product allows a high molecular-weight polymer to be readily obtained, and improvement in the cohesive strength can be expected. Note, however, that the present embodiment is not limited to this, and the (meth)acrylic ester polymer (A) may be one polymerized in the absence of a solvent.

The polymerization form of the (meth)acrylic ester polymer (A) may be a random copolymer or may also be a block copolymer.

The weight-average molecular weight of the (meth)acrylic ester polymer (A) may be preferably 10,000 to 3,000,000, more preferably 100,000 to 2,500,000, particularly preferably 250,000 to 2,200,000, further preferably 400,000 to 1,800,000, and most preferably 600,000 to 1,500,000 from the viewpoint of making molecules of the (meth)acrylic ester polymer (A) sufficiently entangled with each other so that the desired cohesive strength can be readily obtained. As used in the present specification, the weight-average molecular weight refers to a standard polystyrene equivalent value that is measured by using a gel permeation chromatography (GPC) method.

In the pressure sensitive adhesive composition P, one type of the (meth)acrylic ester polymer (A) may be used alone or two or more types may also be used in combination.

### (1-2) Modified Cyclodextrin Multimer (B)

The modified cyclodextrin multimer (B) in the present embodiment is as described previously. One type of the modified cyclodextrin multimer (B) may be used alone or two or more types may also be used in combination.

The content of the modified cyclodextrin multimer (B) in the pressure sensitive adhesive composition P may be preferably 0.5 to 100 mass parts, more preferably 1 to 60 mass parts, particularly preferably 2 to 30 mass parts, further preferably 3 to 18 mass parts, and most preferably 4 to 12 mass parts with respect to 100 mass parts of the (meth)acrylic ester polymer (A). This allows the obtained pressure sensitive adhesive to have better pressure sensitive adhesive properties and reworkability.

### (1-3) Crosslinker (C)

The pressure sensitive adhesive composition P may preferably contain crosslinker (C), but may not necessarily have to contain it. It suffices that the crosslinker (C) is reactive with a reactive group of the (meth)acrylic ester polymer (A). Examples of the crosslinker (B) include an isocyanate-based crosslinker, an epoxy-based crosslinker, an amine-based crosslinker, a melamine-based crosslinker, an aziridine-based crosslinker, a hydrazine-based crosslinker, an aldehyde-based crosslinker, an oxazoline-based crosslinker, a metal alkoxide-based crosslinker, a metal chelate-based crosslinker, a metal salt-based crosslinker, and an ammonium salt-based crosslinker. When the (meth)acrylic ester polymer (A) contains a hydroxyl group-containing monomer as a constituent monomer, it may be preferred to use, among the above, an isocyanate-based crosslinker that is highly reactive with hydroxyl groups. One type of the crosslinker (B) may be used alone or two or more types may also be used in combination.

The isocyanate-based crosslinker contains at least a polyisocyanate compound. Examples of the polyisocyanate compound include aromatic polyisocyanates such as tolylene diisocyanate, diphenylmethane diisocyanate, and xylylene diisocyanate, aliphatic polyisocyanates such as hexamethylene diisocyanate, alicyclic polyisocyanates such as isophorone diisocyanate and hydrogenated diphenylmethane diisocyanate, biuret bodies and isocyanurate bodies thereof, and adduct bodies that are reaction products with low molecular active hydrogen-containing compounds such as ethylene glycol, propylene glycol, neopentyl glycol, trimethylol propane, and castor oil. Among these, from the viewpoint of reactivity with hydroxyl groups, trimethylolpropane-modified aromatic polyisocyanate may be preferred, and trimethylolpropane-modified tolylene diisocyanate may be particularly preferred.

The content of the crosslinker (C) in the pressure sensitive adhesive composition P may be preferably 0.001 to 10 mass parts, particularly preferably 0.01 to 5 mass parts, and further preferably 0.1 to 1 mass parts with respect to 100 mass parts of the (meth)acrylic ester polymer (A). When the content of the crosslinker (B) falls within the above range, the desired adhesive strength can be readily obtained.

### (1-4) Silane Coupling Agent (D)

The pressure sensitive adhesive composition P may also preferably contain the silane coupling agent (D). This can improve the interfacial adhesion with an adherend even when the adherend is a plastic member or a glass member. This can achieve more excellent bending resistance while maintaining the good reworkability.

The silane coupling agent (D) may be preferably an organosilicon compound having at least one alkoxysilyl group in the molecule, which has satisfactory compatibility with the (meth)acrylic ester polymer (A).

Examples of such a silane coupling agent (D) include polymerizable unsaturated group-containing silicon compounds such as vinyltrimethoxysilane, vinyltriethoxysilane and methacryloxypropyltrimethoxysilane, silicon compounds having an epoxy structure, such as 3-glycidoxypropyltrimethoxysilane and 2-(3,4-epoxycyclohexyl)ethyltrimethoxysilane, mercapto group-containing silicon compounds such as 3-mercaptopropyltrimethoxysilane, 3-mercaptopropyltriethoxysilane and 3-mercaptopropyldimethoxymethylsilane, amino group-containing silicon compounds such as 3-aminopropyltrimethoxysilane, N-(2-aminoethyl)-3-aminopropyltrimethoxysilane and N-(2-aminoethyl)-3-aminopropylmethyldimethoxysilane, 3-chloropropyltrimethoxysilane, 3-isocyanatepropyltriethoxysilane, and condensates of at least one of these and an alkyl group-containing silicon compound such as methyltriethoxysilane, ethyltriethoxysilane, methyltrimethoxysilane and ethyltrimethoxysilane. These may each be used alone or two or more types may also be used in combination.

The content of the silane coupling agent in the pressure sensitive adhesive composition P may be preferably 0.01 to 1.2 mass parts, particularly preferably 0.05 to 0.8 mass parts, and further preferably 0.1 to 0.4 mass parts with respect to 100 mass parts of the (meth)acrylic ester polymer (A).

### (1-5) Various Additives

If desired, the pressure sensitive adhesive composition P can contain one or more of various additives, such as an antirust, an ultraviolet absorber, an infrared absorber, an antistatic, a tackifier, an antioxidant, a light stabilizer, a softening agent, a refractive index adjuster, and a colorant, which are commonly used in acrylic-based pressure sensitive adhesives. The additives which constitute the pressure sensitive adhesive composition P are deemed not to include a polymerization solvent or a diluent solvent, which will be described later.

### (2) Preparation of Pressure Sensitive Adhesive Composition P

The pressure sensitive adhesive composition P can be prepared through producing the (meth)acrylic ester polymer (A) and mixing the obtained (meth)acrylic ester polymer (A) with the modified cyclodextrin multimer (B) and optionally adding the crosslinker (C), the silane coupling agent (D), other additives, etc.

The (meth)acrylic ester polymer (A) can be produced by polymerizing a mixture of the monomers which constitute the polymer using a commonly-used radical polymerization method. Polymerization of the (meth)acrylic ester polymer (A) may be preferably carried out by a solution polymerization method, if desired, using a polymerization initiator. However, the present invention is not limited to this, and the polymerization may be performed without a solvent. Examples of the polymerization solvent include ethyl acetate, n-butyl acetate, isobutyl acetate, toluene, acetone, hexane, and methyl ethyl ketone, and two or more types thereof may also be used in combination.

Examples of the polymerization initiator include azo-based compounds and organic peroxides and two or more types thereof may also be used in combination. Examples of the azo-based compounds include 2,2′-azobisisobutyronitrile, 2,2′-azobis(2-methylbutyronitrile), 1,1′-azobis(cyclohexane 1-carbonitrile), 2,2′-azobis(2,4-dimethylvaleronitrile), 2,2′-azobis(2,4-dimethyl-4-methoxyvaleronitrile), dimethyl 2,2′-azobis(2-methylpropionate), 4,4′-azobis(4-cyanovaleric acid), 2,2′-azobis(2-hydroxymethylpropionitrile), and 2,2′-azobis[2-(2-imidazolin-2-yl)propane].

Examples of the organic peroxides include benzoyl peroxide, t-butyl perbenzoate, cumene hydroperoxide, diisopropyl peroxydicarbonate, di-n-propyl peroxydicarbonate, di(2-ethoxyethyl)peroxydicarbonate, t-butyl peroxyneodecanoate, t-butyl peroxybivalate, (3,5,5-trimethylhexanoyl)peroxide, dipropionyl peroxide, and diacetyl peroxide.

In the above polymerization step, the weight-average molecular weight of the polymer to be obtained can be adjusted by compounding a chain transfer agent such as 2-mercaptoethanol.

After the (meth)acrylic ester polymer (A) is obtained, the pressure sensitive adhesive composition P (coating solution) diluted with a solvent may be obtained through adding the modified cyclodextrin multimer (B) and optionally the crosslinker (C), a diluent solvent, the silane coupling agent (D), other additives, etc. to the solution of the (meth)acrylic ester polymer (A) and sufficiently mixing them. If any of the above components is in the form of a solid, or if precipitation occurs when the component is mixed with another component in an undiluted state, the component may be preliminarily dissolved in or diluted with a diluent solvent alone and then mixed with the other component.

Examples of the above diluent solvent for use include aliphatic hydrocarbons such as hexane, heptane and cyclohexane, aromatic hydrocarbons such as toluene and xylene, halogenated hydrocarbons such as methylene chloride and ethylene chloride, alcohols such as methanol, ethanol, propanol, butanol and 1-methoxy-2-propanol, ketones such as acetone, methyl ethyl ketone, 2-pentanone, isophorone and cyclohexanone, esters such as ethyl acetate and butyl acetate, and cellosolve-based solvents such as ethyl cellosolve.

The concentration/viscosity of the coating solution thus prepared is not particularly limited and can be appropriately selected depending on the situation, provided that the concentration/viscosity is within any range in which the coating is possible. For example, the pressure sensitive adhesive composition P may be diluted to a concentration of 10 to 60 mass %. When obtaining the coating solution, the addition of a diluent solvent or the like is not a necessary condition, and the diluent solvent may not be added if the pressure sensitive adhesive composition P has a viscosity or the like that enables the coating. In this case, the pressure sensitive adhesive composition P may be a coating solution in which the polymerization solvent itself for the (meth)acrylic ester polymer (A) is used as a diluent solvent.

### <Pressure Sensitive Adhesive>

The pressure sensitive adhesive according to an embodiment of the present invention is obtained from the aforementioned pressure sensitive adhesive composition. The pressure sensitive adhesive according to the present embodiment may be one obtained by crosslinking the pressure sensitive adhesive composition or may also be one that contains the pressure sensitive adhesive without being crosslinked. The pressure sensitive adhesive according to the present embodiment may be preferably one obtained by crosslinking the aforementioned pressure sensitive adhesive composition P (in particular, the pressure sensitive adhesive composition P containing the crosslinker (C)).

Crosslinking of the pressure sensitive adhesive composition P can be usually performed by heat treatment. Drying treatment when volatilizing a diluent solvent and the like from the coating film of the pressure sensitive adhesive composition P applied to a desired object can also serve as the above heat treatment.

The heating temperature of the heat treatment may be preferably 50° C. to 150° C. and particularly preferably 70° C. to 120° C. The heating time may be preferably 10 seconds to 10 minutes and particularly preferably 50 seconds to 2 minutes.

After the heat treatment, if necessary, an aging period at an ordinary temperature (e.g., 23° C., 50% RH) for about 1 to 2 weeks may be provided. When the aging period is necessary, the pressure sensitive adhesive is formed after the aging period has elapsed, while when the aging period is not necessary, the pressure sensitive adhesive is formed after the heat treatment has been completed.

The above heat treatment (and aging) allows the (meth)acrylic ester polymer (A) to be crosslinked via the crosslinker (B), and the pressure sensitive adhesive can thus be obtained.

### (1) Physical Properties of Pressure Sensitive Adhesive

### (1-1) Gel Fraction

The gel fraction of the pressure sensitive adhesive according to the present embodiment may be preferably 1% to 92% and more preferably 1% to 90%. This allows the pressure sensitive adhesive to have good cohesive strength and also to readily exhibit a predetermined adhesive strength. Furthermore, from the viewpoint of achieving both the adhesive strength and the reworkability, the gel fraction may be preferably 10% to 87%, more preferably 30% to 85%, particularly preferably 40% to 83%, and further preferably 50% to 82%. Details of the measurement method for the gel fraction in the present specification are as described in the Testing Example, which will be described later.

### (1-2) 100% Modulus

The 100% modulus of the pressure sensitive adhesive according to the present embodiment may be preferably 0.13 N/mm² or less, more preferably 0.11 N/mm² or less, particularly preferably 0.09 N/mm² or less, further preferably 0.07 N/mm² or less, and most preferably 0.05 N/mm² or less. This allows the pressure sensitive adhesive to readily develop the desired adhesive strength and, for example, the pressure sensitive adhesive can be more excellent in the bending resistance. The lower limit of the 100% modulus is not particularly limited, but may be preferably 0.001 N/mm² or more, particularly preferably 0.005 N/mm² or more, and further preferably 0.01 N/mm² or more. Details of the measurement method (tensile test) for the 100% modulus in the present specification are as described in the Testing Example, which will be described later.

### (1-3) 500% Modulus

The 500% modulus of the pressure sensitive adhesive according to the present embodiment may be preferably 0.05 to 50 N/mm², more preferably 0.07 to 30 N/mm², particularly preferably 0.1 to 10 N/mm², further preferably 0.12 to 1 N/mm², and most preferably 0.15 to 0.5 N/mm². This allows the pressure sensitive adhesive to readily develop the desired adhesive strength and, for example, the pressure sensitive adhesive can be more excellent in the reworkability or the bending resistance. In particular, the 500% modulus may be preferably 0.16 to 0.19 N/mm² from the viewpoint of a tendency for more excellent reworkability, and may also be preferably 0.19 to 0.25 N/mm² from the viewpoint of a tendency for better bending resistance. Details of the measurement method (tensile test) for the 500% modulus in the present specification are as described in the Testing Example, which will be described later.

### (1-4) Breaking Stress

The breaking stress of the pressure sensitive adhesive according to the present embodiment in a tensile test may be preferably 0.25 N/mm² or more, more preferably 0.3 N/mm² or more, particularly preferably 0.32 N/mm² or more, and further preferably 0.35 N/mm² or more. This allows the pressure sensitive adhesive to exhibit the desired cohesive strength, to readily develop the adhesive strength, and to be excellent in the reworkability. The development of the above adhesive strength tends to result in, for example, more excellent bending resistance. The upper limit of the above breaking stress is not particularly limited, but may be preferably 100 N/mm² or less, more preferably 50 N/mm² or less, and particularly preferably 10 N/mm² or less. From the viewpoint of making the adhesive strength and reworkability good, the upper limit of the breaking stress may be preferably 1 N/mm² or less and preferably 0.6 N/mm² or less, and from the viewpoint of also making the bending resistance better, it may be further preferably 0.35 N/mm² or less and most preferably less than 0.35 N/mm². Details of the measurement method (tensile test) for the breaking stress in the present specification are as described in the Testing Example, which will be described later.

### (1-5) Breaking Elongation

The breaking elongation of the pressure sensitive adhesive according to the present embodiment in a tensile test may be preferably 650% or more, more preferably 680% or more, particularly preferably 700% or more, and further preferably 720% or more. This allows the pressure sensitive adhesive to exhibit the desired cohesive strength, and the pressure sensitive adhesive can thereby readily develop the adhesive strength and can be excellent in the reworkability; for example, the pressure sensitive adhesive can be more excellent in the bending resistance. The upper limit of the breaking elongation is not particularly limited, but may be preferably 4,000% or less, more preferably 3,000% or less, particularly preferably 2,000% or less, and further preferably 1,000% or less. Details of the measurement method (tensile test) for the breaking elongation in the present specification are as described in the Testing Example, which will be described later.

### (1-6) Storage Elastic Modulus G′

The storage elastic modulus G′ of the pressure sensitive adhesive according to the present embodiment at 23° C. may be preferably 0.008 to 2 MPa, more preferably 0.01 to 1 MPa, particularly preferably 0.02 to 0.5 MPa, further preferably 0.03 to 0.1 MPa, and most preferably 0.04 to 0.08 MPa. This allows the pressure sensitive adhesive to exhibit the desired cohesive strength, to readily develop the adhesive strength, and to be excellent in the reworkability. The development of the above adhesive strength may result in, for example, more excellent bending resistance. Details of the measurement method for the storage elastic modulus G′ in the present specification are as described in the Testing Example, which will be described later.

### (2) Uses of Pressure Sensitive Adhesive

The pressure sensitive adhesive according to the present embodiment may be preferably used to bond one target adherend and another adherend. These adherends may have smooth surfaces or may also have surfaces with irregularities. The pressure sensitive adhesive according to the present embodiment may be preferably used to bond an optical member and another optical member, and may be particularly preferably used to bond a display body structural member and another display body structural member. The pressure sensitive adhesive according to the present embodiment may also be preferably used to bond a bendable member and another bendable member that constitute a device that is repeatedly bent, and these bendable members may be further preferably optical members, in particular display body structural members. The specific contents of adherends will be described later.

### <Pressure Sensitive Adhesive Sheet>

The pressure sensitive adhesive sheet according to an embodiment of the present invention has at least a pressure sensitive adhesive layer, and may be preferably obtained by laminating a release sheet on one surface of the pressure sensitive adhesive layer or laminating release sheets on both surfaces of the pressure sensitive adhesive layer. The pressure sensitive adhesive that constitutes the pressure sensitive adhesive layer is the pressure sensitive adhesive according to the aforementioned embodiment.

FIG. 1 illustrates a specific configuration as an example of the pressure sensitive adhesive sheet according to the present embodiment.

As illustrated in FIG. 1, a pressure sensitive adhesive sheet 1 according to an embodiment is composed of two release sheets 12a and 12b and a pressure sensitive adhesive layer 11 interposed between the two release sheets 12a and 12b so as to be in contact with release surfaces of the two release sheets 12a and 12b. As used in the present specification, the release surface of a release sheet refers to a surface having releasability in the release sheet, and examples of the release surface include both a surface subjected to release treatment and a surface that exhibits releasability even without being subjected to release treatment.

### 1. Constitutional Elements

### 1-1. Pressure Sensitive Adhesive Layer

The pressure sensitive adhesive that constitutes the pressure sensitive adhesive layer 11 in the present embodiment is the pressure sensitive adhesive according to the aforementioned embodiment.

The thickness of the pressure sensitive adhesive layer 11 in the present embodiment may be preferably 1 to 1,000 μm, more preferably 2 to 500 μm, particularly preferably 5 to 100 μm, further preferably 10 to 60 μm, especially preferably 15 to 40 μm, and most preferably 20 to 30 μm. This allows the pressure sensitive adhesive layer 11 to readily exhibit the desired adhesive strength and to be excellent in the reworkability. Exhibition of the above adhesive strength provides, for example, more excellent bending resistance. Moreover, the above thickness provides excellent visibility.

### 1-2. Release Sheets

The release sheets 12a and 12b are to protect the pressure sensitive adhesive layer 11 until the use of the pressure sensitive adhesive sheet 1 and are removed when using the pressure sensitive adhesive sheet 1 (pressure sensitive adhesive layer 11). In the pressure sensitive adhesive sheet 1 according to the present embodiment, one or both of the release sheets 12a and 12b may not necessarily be required.

Examples of the release sheets 12a and 12b for use include a polyethylene film, a polypropylene film, a polybutene film, a polybutadiene film, a polymethylpentene film, a polyvinyl chloride film, a vinyl chloride copolymer film, a polyethylene terephthalate film, a polyethylene naphthalate film, a polybutylene terephthalate film, a polyurethane film, an ethylene vinyl acetate film, an ionomer resin film, an ethylene-(meth)acrylic acid copolymer film, an ethylene-(meth)acrylic ester copolymer film, a polystyrene film, a polycarbonate film, a polyimide film, and a fluorine resin film. Crosslinked films thereof may also be used. Laminate films each obtained by laminating a plurality of such films may also be used.

It may be preferred to perform release treatment for the release surfaces (in particular, surfaces to be in contact with the pressure sensitive adhesive layer 11) of the release sheets 12a and 12b. Examples of a release agent to be used for the release treatment include alkyd-based, silicone-based, fluorine-based, unsaturated polyester-based, polyolefin-based, and wax-based release agents. One of the release sheets 12a and 12b may be preferably a tight release sheet that requires higher peeling force while the other may be an easy release sheet that requires lower peeling force.

The thickness of the release sheets 12a and 12b is not particularly limited, but may be usually about 20 to 150 μm.

### 2. Physical Properties

### (1) Haze Value

The haze value of the pressure sensitive adhesive layer 11 in the present embodiment may be preferably 0.01% to 50%, more preferably 0.1% to 35%, particularly preferably 0.4% to 20%, further preferably 0.7% to 10%, especially preferably 1% to 7%, and most preferably 2% to 4%. This allows the product to be excellent in the light transmittance, to be suitable for optical use, particularly for displays, and to be excellent in the image visibility from an oblique angle on a display. The haze value in the present specification is a value measured in accordance with JIS K7136: 2000.

### (2) Total Luminous Transmittance

The total luminous transmittance of the pressure sensitive adhesive layer 11 in the present embodiment may be preferably 80% or more, more preferably 85% or more, particularly preferably 88% or more, and further preferably 89% or more. This allows the product to be excellent in the light transmittance and to be suitable for optical use, particularly for displays. The upper limit of the above total luminous transmittance is not particularly limited and may be 100%, but from the viewpoint of the image visibility from an oblique angle on a display, it may be preferably 98% or less, particularly preferably 95% or less, and further preferably 93% or less. The total luminous transmittance in the present specification is a value measured in accordance with JIS K7361-1: 1997.

### (3) Adhesive Strength

The adhesive strength of the pressure sensitive adhesive sheet 1 according to the present embodiment to a non-alkali glass plate at 23° C. may be preferably 1.0 N/25 mm or more, more preferably 1.9 N/25 mm or more, particularly preferably 2.5 N/25 mm or more, further preferably 3.0 N/25 mm or more, and most preferably 4.0 N/25 mm or more as the lower limit. When the lower limit of the adhesive strength satisfies the above, the pressure sensitive adhesive sheet 1 can exhibit sufficient interfacial adhesion to an adherend and, for example, the bending resistance can be more excellent. The upper limit of the above adhesive strength may be preferably 50 N/25 mm or less, more preferably 35 N/25 mm or less, particularly preferably 20 N/25 mm or less, further preferably 10 N/25 mm or less, and most preferably 4 N/25 mm or less. When the upper limit of the adhesive strength satisfies the above, good reworkability can be obtained, and the adherend can be easily reused even if a lamination error occurs. In the pressure sensitive adhesive layer 1 according to the present embodiment, the pressure sensitive adhesive contains a modified cyclodextrin multimer, and it is thereby possible, as described above, to achieve the adhesive strength that is excellent in the interfacial adhesion and the bending resistance depending on the application and exhibits good reworkability. When measuring the adhesive strength of the pressure sensitive adhesive sheet 1 according to the present embodiment to a non-alkali glass plate at 23° C., it is preferred that the pressure sensitive adhesive should not undergo cohesive failure. The adhesive strength in the present specification refers basically to a peel strength that is measured using a method of 180° peeling in accordance with JIS Z0237: 2009, and a specific testing method is as described in the Testing Example, which will be described later.

### 3. Production of Pressure Sensitive Adhesive Sheet

An example of producing the pressure sensitive adhesive sheet 1 will be described for a case in which the above pressure sensitive adhesive composition P is used. This example may include coating the release surface of one release sheet 12a (or 12b) with a coating solution of the above pressure sensitive adhesive composition P, performing heat treatment to thermally crosslink the pressure sensitive adhesive composition P to form a coating layer, and then overlapping the release surface of the other release sheet 12b (or 12a) on the coating layer. When an aging period is necessary, the above coating layer may become the pressure sensitive adhesive layer 11 after the aging period has elapsed, while when an aging period is not necessary, the above coating layer formed as such may be the pressure sensitive adhesive layer 11. The above pressure sensitive adhesive sheet 1 can thus be obtained. Conditions for the heat treatment and aging are as previously described.

Examples of the method of coating with the above coating solution of the pressure sensitive adhesive composition P include a bar coating method, a knife coating method, a roll coating method, a blade coating method, a die coating method, and a gravure coating method.

### 4. Use Applications

The pressure sensitive adhesive layer of the pressure sensitive adhesive sheet according to the present embodiment may be preferably used to bond one target adherend and another adherend. The type of adherend is not particularly limited, and examples thereof include plastic, metal, glass, ceramics, pottery, rubber, paper, and nonwoven fabric. The adherend may be one having flexibility or may also be a rigid body. The product that the adherend constitutes is also not particularly limited.

The pressure sensitive adhesive sheet according to the present embodiment may be preferably used to bond an optical member and another optical member, and may be particularly preferably used to bond a display body structural member and another display body structural member. The pressure sensitive adhesive sheet according to the present embodiment may also be preferably used to bond a bendable member and another bendable member that constitute a device that is repeatedly bent, and these bendable members may be further preferably optical members, in particular display body structural members.

### <Display Body>

The display body according to the present embodiment includes a first display body structural member, a second display body structural member, and a pressure sensitive adhesive layer that bonds the first display body structural member and the second display body structural member to each other. The pressure sensitive adhesive layer is formed of the pressure sensitive adhesive according to the aforementioned embodiment or may be the pressure sensitive adhesive layer 11 of the aforementioned pressure sensitive adhesive sheet 1.

Examples of the display body include a liquid crystal (LCD) display, a light emitting diode (LED) display, an organic electroluminescence (organic EL) display, and electronic paper, and the display body may be a touch panel. The display body may be a member that constitutes a part of each of these examples.

One or both of the first display body structural member and the second display body structural member may be flexible, or both may be rigid bodies. The pressure sensitive adhesive layer obtained from the aforementioned pressure sensitive adhesive composition P allows the first display body structural member, which is a rigid body, and the second display body structural member, which is also a rigid body, to be bonded together without any problems.

The first display body structural member may be preferably a protective panel made of a glass plate, a plastic plate, or the like or a laminate that includes a glass plate or a plastic plate. The first display body structural member may have steps on the surface on the pressure sensitive adhesive layer side. In this case, specifically, the first display body structural member may preferably have steps due to a printed layer. This printed layer is generally formed in the shape of a frame.

The above glass plate is not particularly limited, and examples thereof include chemically strengthened glass, non-alkali glass, quartz glass, soda-lime glass, barium/strontium-containing glass, aluminosilicate glass, lead glass, borosilicate glass, and barium borosilicate glass. The thickness of the glass plate is not particularly limited, but may be usually 0.1 to 5 mm and preferably 0.2 to 2 mm.

The above plastic plate is not particularly limited, and examples thereof include acrylic plates and polycarbonate plates. The thickness of the plastic plate is not particularly limited, but may be usually 0.2 to 5 mm and preferably 0.4 to 3 mm.

One surface or both surfaces of the above glass plate or plastic plate may be provided with various functional layers (such as an electrode layer, a silica layer, a hard coat layer, and an antiglare layer) or may also be laminated with an optical member.

The second display body structural member may be preferably an optical member, a display body module (e.g., a liquid crystal (LCD) module, a light emitting diode (LED) module, an organic electroluminescence (organic EL) module, or the like), an optical member as a part of the display body module, or a laminate including the display body module, to which the first display body structural member should be bonded.

The display body according to the present embodiment is excellent in the image visibility from an oblique angle in addition to the image visibility from the front because the pressure sensitive adhesive layer is previously described one.

### <Repetitive Bending Laminate Member>

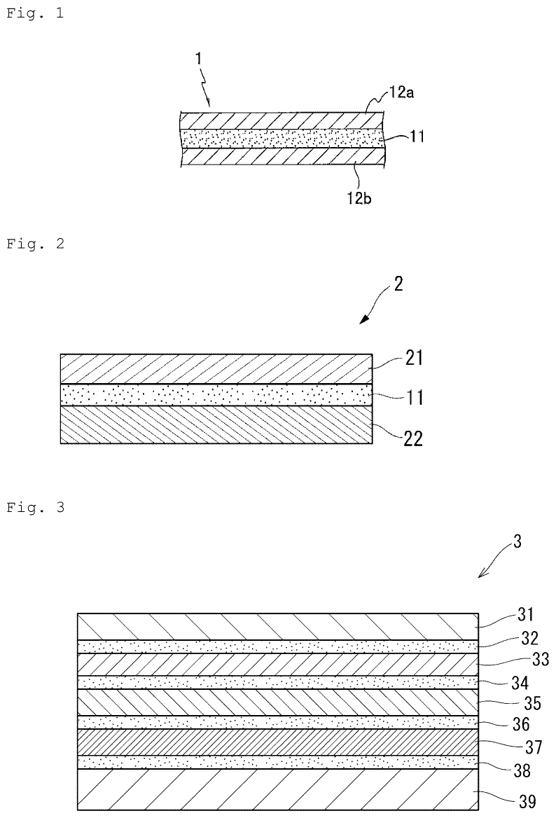

As illustrated in FIG. 2, a repetitive bending laminate member 2 according to the present embodiment is configured to include a first bendable member 21 (a bendable member), a second bendable member 22 (another bendable member), and a pressure sensitive adhesive layer 11 that is located between the first bendable member 21 and the second bendable member 22 and bonds them to each other.

The pressure sensitive adhesive layer 11 in the above repetitive bending laminate member 2 is formed of the pressure sensitive adhesive according to the aforementioned embodiment or may be the pressure sensitive adhesive layer 11 of the aforementioned pressure sensitive adhesive sheet 1.

The repetitive bending laminate member 2 may be a repetitive bending device itself or may also be a member constituting a part of the repetitive bending device. The repetitive bending device may be preferably, but is not limited to, a display that can be repeatedly bent (including being folded) (repetitive bending display). Examples of such repetitive bending devices include organic electroluminescence (organic EL) displays, electrophoretic displays (electronic paper), liquid crystal displays using plastic substrates (films) as the substrates, and foldable displays. The repetitive bending devices may be touch panels.

The first bendable member 21 and the second bendable member 22 may be members that can be repeatedly bent (including being folded), and examples thereof include cover films, gas barrier films, hard coat films, polarization films (polarization plates), polarizers, retardation films (retardation plates), viewing angle compensation films, brightness enhancement films, contrast enhancement films, diffusion films, semi-transmissive reflective films, electrode films, transparent conductive films, metal mesh films, flexible glass, film sensors (touch sensor films), liquid crystal polymer films, luminescent polymer films, film-like liquid crystal modules, organic EL modules (organic EL films, organic EL elements), electronic paper modules (film-like electronic paper), and thin film transistor (TFT) substrates.

At least one of the first bendable member 21 and the second bendable member 22 may be a polyimide film or a laminate including a polyimide film on the pressure sensitive adhesive layer 11 side. A polyimide film generally has low interfacial adhesion with a pressure sensitive adhesive layer, but according to the pressure sensitive adhesive layer 11 of the present embodiment, even when the polyimide film is an adherend, excellent bending resistance can be obtained.

The Young's moduli of the first bendable member 21 and second bendable member 22 may each be preferably 0.1 to 10 GPa, particularly preferably 0.5 to 7 GPa, and further preferably 1.0 to 5 GPa. When the Young's moduli of the first bendable member 21 and second bendable member 22 fall within such ranges, each bendable member can be readily bent repeatedly.

Additionally or alternatively, when each of the first bendable member 21 and the second bendable member 22 has an angle (a folding angle on the acute angle side formed between the surfaces of the bendable members) at which it can be folded without cracking or irreversible deformation when folded at its center line, the angle may be preferably 150° or less, more preferably 90° or less, particularly preferably 60° or less, further preferably 30° or less, and most preferably 10° or less. This allows the repetitive bending device to be readily obtained, which will be described later.

The thickness of each of the first bendable member 21 and the second bendable member 22 may be preferably 10 to 3,000 μm, particularly preferably 25 to 1,000 μm, and further preferably 50 to 500 μm. When the thicknesses of the first bendable member 21 and second bendable member 22 fall within such ranges, it may be easy to repeatedly bend each bendable member.

To produce the above repetitive bending laminate member 2, as an example, one release sheet 12a of the pressure sensitive adhesive sheet 1 is removed, and the exposed pressure sensitive adhesive layer 11 of the pressure sensitive adhesive sheet 1 is bonded to one surface of the first bendable member 21.

After that, the other release sheet 12b is removed from the pressure sensitive adhesive layer 11 of the pressure sensitive adhesive sheet 1, and the exposed pressure sensitive adhesive layer 11 of the pressure sensitive adhesive sheet 1 and the second bendable member 22 are bonded to each other to obtain the repetitive bending laminate member 2. As another example, the order of bonding the first bendable member 21 and the second bendable member 22 may be reversed.

### <Repetitive Bending Device>

The repetitive bending device according to the present embodiment, which includes the above repetitive bending laminate member 2, may be composed only of the repetitive bending laminate member 2 or may also be configured to include one or more repetitive bending laminate members 2 and another bendable member. When a repetitive bending laminate member 2 and another repetitive bending laminate member 2 are laminated or when a repetitive bending laminate member 2 and another bendable member are laminated, it may be preferred to laminate them via the pressure sensitive adhesive layer 11 of the aforementioned pressure sensitive adhesive sheet 1.

The repetitive bending device according to the present embodiment has excellent bending resistance because the pressure sensitive adhesive layer is composed of the aforementioned pressure sensitive adhesive, and even when the repetitive bending device is repeatedly bent, floating or delamination is unlikely to occur at the interface between the pressure sensitive adhesive layer and the adherend at the bent portion.

FIG. 3 illustrates a repetitive bending device as an example in the present embodiment. The repetitive bending device according to the present invention is not limited to that repetitive bending device.

As illustrated in FIG. 3, a repetitive bending device 3 according to the present embodiment may be configured by laminating a cover film 31, a first pressure sensitive adhesive layer 32, a polarization film 33, a second pressure sensitive adhesive layer 34, a touch sensor film 35, a third pressure sensitive adhesive layer 36, an organic EL element 37, a fourth pressure sensitive adhesive layer 38, and a TFT substrate 39 in this order from the top. The above cover film 31, polarization film 33, touch sensor film 35, organic EL element 37, and TFT substrate 39 correspond to bendable members.

At least one of the first pressure sensitive adhesive layer 32, the second pressure sensitive adhesive layer 34, the third pressure sensitive adhesive layer 36, and the fourth pressure sensitive adhesive layer 38 may be the pressure sensitive adhesive layer 11 of the aforementioned pressure sensitive adhesive sheet 1. Any two or more of the first pressure sensitive adhesive layer 32, the second pressure sensitive adhesive layer 34, the third pressure sensitive adhesive layer 36, and the fourth pressure sensitive adhesive layer 38 may each be preferably the pressure sensitive adhesive layer 11 of the aforementioned pressure sensitive adhesive sheet 1. Most preferably, all of the pressure sensitive adhesive layers 32, 34, 36, and 38 are each the pressure sensitive adhesive layer 11 of the pressure sensitive adhesive sheet 1.

The aforementioned embodiments are described to facilitate understanding of the present invention and are not described to limit the present invention. It is therefore intended that the elements disclosed in the above embodiments include all design changes and equivalents to fall within the technical scope of the present invention.

For example, one or both of the release sheets 12a and 12b in the pressure sensitive adhesive sheet 1 may be omitted, and one or more desired bendable members may be laminated as substitute for the release sheets 12a and/or 12b.

In the present specification, unless otherwise specified, the statement of “X to Y” (X and Y are arbitrary numbers) encompasses not only the meaning of “X or more and Y or less” but also the meaning of “preferably more than X” or “preferably less than Y.” In addition, unless otherwise specified, the statement of “X or more” (X is an arbitrary number) encompasses the meaning of “preferably more than X,” and the statement of “Y or less” (Y is an arbitrary number) encompasses the meaning of “preferably less than Y.”

### EXAMPLES

Hereinafter, the present invention will be described further specifically with reference to examples, etc., but the scope of the present invention is not limited to these examples, etc.

### Preparation Example 1

Into 40 ml of anhydrous N,N-dimethylformamide, 5.83 g (5.10 mmol) of β-cyclodextrin (available from NACALAI TESQUE, INC.) was dissolved. Into 10 ml of anhydrous N,N-dimethylformamide, 7.82 g (3.40 mmol) of poly(propylene glycol) tolylene 2,4-diisocyanate (Mn: 2,300) was dissolved. The two solutions were mixed, and 215 mg (0.34 mmol) of dibutyltin dilaurate was added as a catalyst to the mixed solution, which was then stirred for 12 hours at room temperature under a nitrogen atmosphere. The obtained reaction solution was poured into diethyl ether, and the precipitate was collected by reprecipitation.

After that, 1,050 mg of the obtained precipitate was dispersed in 25 ml (225 mmol) of isopropenyl acetate, to which 17.5 mg (0.10 mmol) of toluenesulfonic acid was added, and the mixture was stirred at 70° C. for 3 hours. The reaction solution was dried under reduced pressure, and the obtained solid was washed with a 10% sodium bicarbonate aqueous solution; thereafter, chloroform was added and the organic layer was collected by a separation operation. The organic layer was then dried under reduced pressure to obtain 1,355 mg of a pale yellow solid. A part of the obtained pale yellow solid was separated by size exclusion chromatography (SEC) to obtain a dimer of β-cyclodextrin modified with poly(propylene glycol) tolylene 2,4-diisocyanate (modified β-cyclodextrin) (analysis revealed that the separated substance was the dimer).

### Preparation Example 2

A portion of the pale yellow solid obtained in Preparation Example 1 was obtained as a mixture of monomers and multimers of β-cyclodextrin modified with poly(propylene glycol) tolylene 2,4-diisocyanate (modified β-cyclodextrin) (analysis revealed that the obtained substance was a mixture of monomers and dimers).

### Preparation Example 3

To 8.5 ml of isopropenyl acetate as a solvent, 1.8 g of β-cyclodextrin (available from NACALAI TESQUE, INC.) and 47 mg of p-toluenesulfonic acid monohydrate as a catalyst were added and reacted at 70° C. for 16 hours. After the reaction solution was distilled under reduced pressure and the obtained solid was washed with a 10 mass % of sodium carbonate aqueous solution, acetylated β-cyclodextrin (monomer) was obtained as a white solid through extraction with chloroform and recrystallization with acetone.

### Example 1

### 1. Preparation of (Meth)Acrylic Ester Polymer (A)

The (meth)acrylic ester polymer (A) was prepared by using a solution polymerization method to copolymerize 45 mass parts of 2-ethylhexyl acrylate, 50 mass parts of n-butyl acrylate, 4.5 mass parts of 4-hydroxybutyl acrylate, and 0.5 mass parts of acrylic acid. The molecular weight of the (meth)acrylic ester polymer (A) was measured by the method to be described later. The weight-average molecular weight (Mw) was 1,200,000.

### 2. Preparation of Pressure Sensitive Adhesive Composition

Coating solution of the pressure sensitive adhesive composition P was obtained through mixing and sufficiently stirring 100 mass parts (solid content equivalent, here and hereinafter) of the (meth)acrylic ester polymer (A) obtained in the above step 1, 5 mass parts of the dimer of modified β-cyclodextrin (modified (CD) prepared in Preparation Example 1 as the modified cyclodextrin multimer (B), 0.75 mass parts of an isocyanate-based crosslinker (C1: available from Soken Chemical & Engineering Co., Ltd., product name “TD-75”) as the crosslinker (C), and 0.25 mass parts of 3-glycidoxypropyltrimethoxysilane (D1) as the silane coupling agent (D) and diluting the mixture with methyl ethyl ketone.

### 3. Production of Pressure Sensitive Adhesive Sheet

The release-treated surface of a tight release sheet (available from LINTEC Corporation, product name “SP-PET752150”) obtained by release-treating one surface of a polyethylene terephthalate film with a silicone-based release agent was coated with the coating solution of the pressure sensitive adhesive composition P obtained in the above step 2 by using a knife coater, and heat treatment was performed at 90° C. for 1 minute to form the pressure sensitive adhesive layer having a thickness of 25 μm. Subsequently, the release-treated surface of an easy release sheet (available from LINTEC Corporation, product name “SP-PET381130”) obtained by release-treating one surface of a polyethylene terephthalate film with a silicone-based release agent was bonded to the surface of the pressure sensitive adhesive layer opposite to the tight release sheet. The pressure sensitive adhesive sheet was thus produced, having a configuration of tight release sheet/pressure sensitive adhesive layer (thickness: 25 μm)/easy release sheet.

Here, the aforementioned number-average molecular weight (Mn) and weight-average molecular weight (Mw) each refer to a weight-average molecular weight that is measured as a standard polystyrene equivalent value under the following conditions using gel permeation chromatography (GPC) (GPC measurement).

### «Measurement Conditions»

Measurement device: HLC-8320 available from Tosoh Corporation
GPC columns (passing through in the following order): available from Tosoh Corporation
   TSK gel super H-H
   TSK gel super HM-H
   TSK gel super H2000
Solvent for measurement: tetrahydrofuran
Measurement temperature: 40° C.

The thickness of the above pressure sensitive adhesive layer is a value measured according to JIS K7130 using a constant-pressure thickness meter (available from TECLOCK Co., Ltd., product name “PG-02”).

### Examples 2 to 5 and Comparative Examples 1 and 2

Pressure sensitive adhesive sheets were produced in the same manner as in Example 1 except that the composition and weight-average molecular weight (Mw) of the (meth)acrylic ester polymer (A), the type and compounding amount of the modified cyclodextrin multimer (B), the type and compounding amount of the crosslinker (C), and the type and compounding amount of the silane coupling agent (D) were as listed in Table 1.

Table 1 lists the composition of the (meth)acrylic ester polymer (A) and the compounding amount of each component (mass parts per 100 mass parts of the (meth)acrylic ester polymer (A)). The simplified names listed in Table 1 and additional information are as follows.

{(Meth) Acrylic Ester Polymer (a)}
2EHA: 2-ethylhexyl acrylate
BA: n-butyl acrylate
4HBA: 4-hydroxybutyl acrylate
AA: acrylic acid

### {Modified Cyclodextrin Multimer (B)}

Modified βCD dimer: those prepared in Preparation Example 1
Modified βCD monomer/multimer mixture: those prepared in Preparation Example 2
Modified βCD monomer: those prepared in Preparation Example 3 (for convenience, listed in the column for the modified cyclodextrin multimer (B))

### {Crosslinker (C)}

C1: isocyanate-based crosslinker (available from Soken Chemical & Engineering Co., Ltd., product name “TD-75”)
C2: isocyanate-based crosslinker (available from Mitsui Chemicals, Inc., product name “TAKENATE D-110N”)

### {Silane Coupling Agent (D)}

D1: 3-glycidoxypropyltrimethoxysilane
D2: 3-glycidoxypropylmethyldiethoxysilane

### <Testing Example 1> (Measurement of Gel Fraction)

The pressure sensitive adhesive sheet produced in each of Examples and Comparative Examples was cut into a size of 80 mm×80 mm, the pressure sensitive adhesive layer was wrapped in a polyester mesh (mesh size of 200), the mass was weighed with a precision balance, and the mass of the pressure sensitive adhesive alone was calculated by subtracting the mass of the above mesh itself. The mass at that time is M1.

Then, the pressure sensitive adhesive wrapped in the above polyester mesh was immersed in ethyl acetate at room temperature (23° C.) for 24 hours. After that, the pressure sensitive adhesive was taken out, air-dried under an environment of a temperature of 23° C. and a relative humidity of 50% for 24 hours, and further dried in an oven at 80° C. for 12 hours. After the drying, the mass was weighed with a precision balance, and the mass of the pressure sensitive adhesive alone was calculated by subtracting the mass of the mesh itself. The mass at that time is M2. The gel fraction (%) of the pressure sensitive adhesive was calculated by (M2/M1)×100. The results are listed in Table 2.

### <Testing Example 2> (Measurement of Storage Elastic Modulus G′)

A laminate having a thickness of 3 mm was obtained by laminating a plurality of pressure sensitive adhesive layers of the pressure sensitive adhesive sheet produced in each of Examples and Comparative Examples. A cylindrical body (height of 3 mm) having a diameter of 8 mm was punched out from the obtained laminate of the pressure sensitive adhesive layers, and this was used as a sample.

For the above sample, the storage elastic modulus G′ was measured by a torsional shear method in accordance with JIS K7244-1 using a viscoelasticity measurement device (available from Anton Paar, product name “MCR302”) under the following conditions, and the storage elastic modulus (G′) (MPa) at 23° C. was acquired. The results are listed in Table 2.
Measurement frequency: 1 Hz
Measurement temperature: 23° C.

### <Testing Example 3> (Measurement of Moduli, Breaking Stress, and Breaking Elongation)

After laminating a plurality of pressure sensitive adhesive layers of the pressure sensitive adhesive sheet produced in each of Examples and Comparative Examples to a total thickness of 600 μm, a sample of 10 mm width×70 mm length was cut out. The above sample was set in a tensile tester (available from ORIENTEC Co., LTD., product name “TENSILON”) so as to have a sample measurement site of 10 mm width×20 mm length (extension direction) and extended at a tensile speed of 200 mm/min under an environment of 23° C. and 50% RH using the tensile tester. From the stress-strain curve (SS curve) thus obtained, the stress values (moduli: N/mm²) at which the elongation ratios were 100% and 500% were derived. The results are listed in Table 2.

In the above tensile test, the elongation ratio of the sample when it was stretched until it broke was measured as the breaking elongation (%), and the stress value at the time of break was measured as the breaking stress (N/mm²). These results are also listed in Table 2.

### <Testing Example 4> (Measurement of Haze Value)

Each of the pressure sensitive adhesive layers of the pressure sensitive adhesive sheets produced in Examples and Comparative Examples was bonded to glass, and this was used as a sample for measurement. For the above sample for measurement, the haze value (%) was measured in accordance with JIS K7136: 2000 using a haze meter (available from NIPPON DENSHOKU INDUSTRIES CO., LTD., product name “SH-7000”). The results are listed in Table 2.

### <Testing Example 5> (Measurement of Total Luminous Transmittance)

Each of the pressure sensitive adhesive layers of the pressure sensitive adhesive sheets produced in Examples and Comparative Examples was bonded to glass, and this was used as a sample for measurement. For the above sample for measurement, the total luminous transmittance (%) was measured in accordance with JIS K7361-1: 1997 using a haze meter (available from NIPPON DENSHOKU INDUSTRIES CO., LTD., product name “SH-7000”). The results are listed in Table 2.

### <Testing Example 6> (Measurement of Adhesive Strength)

The easy release sheet was removed from each of the pressure sensitive adhesive sheets produced in Examples and Comparative Examples, and the exposed pressure sensitive adhesive layer was bonded to the easy-adhesion layer of a polyethylene terephthalate (PET) film having the easy-adhesion layer (available from TOYOBO CO., LTD., product name “COSMOSHINE A4360,” thickness: 100 μm) to obtain a laminate of tight release sheet/pressure sensitive adhesive layer/PET film. The obtained laminate was cut into a width of 25 mm and a length of 100 mm, and this was used as a sample.

The tight release sheet was removed from the above sample under an environment of 23° C. and 50% RH, and the exposed pressure sensitive adhesive layer was bonded to a non-alkali glass plate (available from Corning, product name “Eagle XG”) and then pressurized in an autoclave available from KURIHARA SEISAKUSHO Co., Ltd. at 0.5 MPa and 50° C. for 20 minutes. After that, the sample was left untouched under a condition of 23° C. and 50% RH for 24 hours. Subsequently, the sample was peeled off from the non-alkali glass plate at a peel speed of 300 mm/min and a peel angle of 180° under a condition of 23° C. and 50% RH hours using a tensile tester (available from ORIENTEC Co., LTD., product name “TENSILON”) to measure the adhesive strength (N/25 mm). The measurement was conducted in accordance with JIS Z0237: 2009 except for the conditions described herein. The results are listed in Table 2. In Comparative Example 2, cohesive failure occurred in the pressure sensitive adhesive layer during the peeling.

### <Testing Example 7> (Evaluation of Reworkability)

The easy release sheet was removed from each of the pressure sensitive adhesive sheets produced in Examples and Comparative Examples, and the exposed pressure sensitive adhesive layer was bonded to the easy-adhesion layer of a polyethylene terephthalate (PET) film having the easy-adhesion layer (available from TOYOBO CO., LTD., product name “COSMOSHINE A4360,” thickness: 50 μm) to obtain a laminate of tight release sheet/pressure sensitive adhesive layer/PET film. The obtained laminate was cut into a width of 25 mm and a length of 100 mm, and this was used as a sample.

The tight release sheet was removed from the above sample under an environment of 23° C. and 50% RH, and the exposed pressure sensitive adhesive layer was bonded to a non-alkali glass plate (available from Corning, product name “Eagle XG”) and then pressurized in an autoclave available from KURIHARA SEISAKUSHO Co., Ltd. at 0.5 MPa and 50° C. for 20 minutes. After that, the sample was left untouched under a condition of 40° C. and 50% RH for 7 days. Subsequently, the sample was left untouched under a condition of 23° C. and 50% RH for 24 hours and was then peeled off from the non-alkali glass plate at a peel speed of 300 mm/min and a peel angle of 180° under a condition of 23° C. and 50% RH using a tensile tester (available from ORIENTEC Co., LTD., product name “TENSILON”) to measure the adhesive strength (N/25 mm). The measurement was conducted in accordance with JIS Z0237: 2009 except for the conditions described herein. The reworkability was then evaluated based on the following criteria. The results are listed in Table 2.

⊚: The sample was able to be peeled off cleanly with an adhesive strength of less than 4 N/25 mm.

◯: The sample was able to be peeled off cleanly with an adhesive strength of 4 N/25 mm or more and less than 30 N/25 mm.

X: An adhesive strength of 30 N/25 mm or more was required, or a haze due to the pressure sensitive adhesive remained on the adherend.

### <Testing Example 8> (Evaluation of Visibility)

Each of the pressure sensitive adhesive sheets obtained in Examples and Comparative Examples was cut into length 70 mm×breadth 70 mm, the pressure sensitive adhesive layer of the pressure sensitive adhesive sheet was bonded so as to be interposed between two soda-lime glass plates (available from Nippon Sheet Glass Company, Ltd., length 70 mm×breadth 70 mm×thickness 1.1 mm), and this was used as a sample.

The above sample was placed directly in front of a display (available from Fujitsu Limited, product name “LITEBOOK A574/H,” size 15.6 inches, resolution 1366×768) that was turned on. At that time, the ARIB multi-format color bar was displayed on the display. Then, under a three-wavelength fluorescent lamp (distance from the fluorescent lamp: 200 cm), the appearance of the display through the sample was determined visually from the front and from an oblique angle (an angle of 45°) to evaluate the visibility (wide-angle visibility) in accordance with the following criteria. The results are listed in Table 2.

⊚: Within the entire area where the sample was placed, there was no difference in the appearance from the front and from the oblique angle.

◯: Within the area where the sample was placed, there were both areas where the appearance from the front and from the oblique angle did not change and areas where the appearance from the oblique angle became darker.

X: Within the entire area where the sample was placed, the appearance from the oblique angle became darker compared to the appearance from the front.

In all cases, the screen was bright when viewed from the front, and the image visibility due to the brightness of the screen was therefore good.

### <Testing Example 9> (Evaluation of Bending Resistance)

One surface of the pressure sensitive adhesive layer of the pressure sensitive adhesive sheet produced in each of Examples and Comparative Examples was bonded to a transparent conductive film of a polyethylene terephthalate film having a surface provided with the transparent conductive film composed of tin-doped indium oxide (ITO) (available from OIKE & Co., Ltd., ITO-PET film, thickness: 125 μm). In addition, the other surface of the above pressure sensitive adhesive layer was bonded to one surface of a polyimide film (thickness: 50 μm). A laminate thus obtained of ITO-PET film/pressure sensitive adhesive layer/polyimide film was cut into a size of 150 mm×50 mm, and this was used as a test piece.

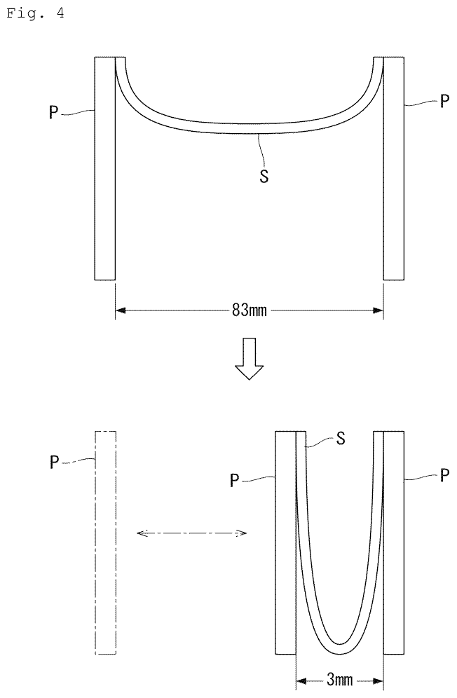

As illustrated in FIG. 4, both end portions of the obtained test piece were fixed to two holding plates of a bending tester with a constant temperature and humidity chamber (available from YUASA SYSTEM Co., Ltd., product name “CL09-type D01-FSC90”). At that time, the test piece was fixed so that the polyimide film side of the laminate was on the inner side of bending. Then, the test piece was bent 200,000 times under a temperature environment of 23° C. with a bending diameter (diameter) of 3 mmφ, a stroke of 80 mm, and a bending speed of 60 rpm.

After performing the above bending test, the change in the appearance of the bent portion of the test piece was visually confirmed, and the bending resistance was evaluated in accordance with the following criteria. The results are listed in Table 2.

⊚: No floating or delamination, and there were no or only minor bent marks.

◯: No floating or delamination, but there were some bent marks.

X: Floating or delamination occurred.

TABLE 1

| | (Meth)acrylic ester | | | | | Modified cyclodextrin | | | | | | |
|---|---|---|---|---|---|---|---|---|---|---|---|---|
| | polymer (A) | | | | | multimer (B) | | | | | Silane coupling | |
| | | | | | | Modified βCD | Modified βCD | Modified βCD | Crosslinker (C) | | agent (D) | |
| | | | | | Molecular | dimer | monomer/multimer | monomer | C1 | C2 | D1 | D2 |
| | Composition | | | | weight | mass | mixture | mass | mass | mass | mass | mass |
| | 2EHA | BA | 4HBA | AA | Mw | parts | mass parts | parts | parts | parts | parts | parts |
| Example 1 | 45 | 50 | 4.5 | 0.5 | 1.2 mil. | 5 | — | — | 0.75 | — | 0.25 | — |
| Example 2 | 45 | 50 | 5 | — | 1.2 mil. | 5 | — | — | — | 0.75 | 0.25 | — |
| Example 3 | 45 | 50 | 5 | — | 0.9 mil. | 10 | — | — | 0.75 | — | — | — |
| Example 4 | 45 | 50 | 5 | — | 1.2 mil. | — | 5 | — | 0.75 | — | — | 0.25 |
| Example 5 | — | 96 | 2 | 2 | 1.6 mil. | 5 | — | — | — | — | — | — |
| Comparative | 45 | 50 | 5 | — | 0.9 mil. | — | — | — | 2 | — | 0.25 | — |
| Example 1 | | | | | | | | | | | | |
| Comparative | 45 | 50 | 5 | — | 1.2 mil. | — | — | 5 | 0.3 | — | 0.25 | — |
| Example 2 | | | | | | | | | | | | |

TABLE 2

| | | Storage | | | | | |
|---|---|---|---|---|---|---|---|
| | Gel | elastic | | | Breaking | Breaking | Haze |
| | fraction | modulus G′ | Moduli (N/mm²) | | stress | elongation | value |
| | % | MPa | 100% | 500% | N/mm² | % | % |
| Example 1 | 77 | 0.04 | 0.047 | 0.211 | 0.342 | 816 | 2.8 |
| Example 2 | 78 | 0.04 | 0.044 | 0.195 | 0.322 | 731 | 2.8 |
| Example 3 | 71 | 0.06 | 0.036 | 0.170 | 0.397 | 881 | 3.4 |
| Example 4 | 82 | 0.04 | 0.048 | 0.186 | 0.414 | 720 | 2.4 |
| Example 5 | <5 | 0.12 | 0.083 | 0.106 | not broken | >4000 | 1.1 |
| Comparative | 93 | 0.06 | 0.150 | broken | 0.289 | 168 | 0.6 |
| Example 1 | | | | | | | |
| Comparative | 84 | 0.05 | 0.041 | 0.174 | 0.223 | 602 | 1.8 |
| Example 2 | | | | | | | |

| | Total | | | Visibility | |
|---|---|---|---|---|---|
| | luminous | Adhesive | | from | |
| | transmittance | strength | | oblique | Bending |
| | % | N/25 mm | Reworkability | angle | resistance |
| Example 1 | 91.9 | 4.9 | ◯ | ⊚ | ⊚ |
| Example 2 | 91.9 | 4.7 | ◯ | ⊚ | ⊚ |
| Example 3 | 91.2 | 3.2 | ⊚ | ⊚ | ◯ |
| Example 4 | 91.8 | 1.9 | ⊚ | ⊚ | ◯ |
| Example 5 | 91.1 | 6.1 | ◯ | ◯ | ◯ |
| Comparative | 91.3 | 0.8 | ⊚ | x | x |
| Example 1 | | | | | |
| Comparative | 91.3 | 1.8; cohesive | x | ◯ | ◯ |
| Example 2 | | failure | | | |

As found from Table 2, the pressure sensitive adhesive sheets produced in Examples had good adhesive strength and were excellent in the reworkability. Moreover, the pressure sensitive adhesive sheets produced in Examples had optical properties such as excellent image visibility from an oblique angle. Furthermore, the pressure sensitive adhesive sheets produced in Examples were excellent in the bending resistance.

### INDUSTRIAL APPLICABILITY

The pressure sensitive adhesive and pressure sensitive adhesive sheet according to the present invention are suitable for bonding a bendable member and another bendable member that constitute a repetitive bending device.

### DESCRIPTION OF REFERENCE NUMERALS

1 Pressure sensitive adhesive sheet
   11 Pressure sensitive adhesive layer
   12a, 12b Release sheet
2 Repetitive bending laminate member
   21 First bendable member
   22 Second bendable member
3 Repetitive bending device
   31 Cover film
   32 First pressure sensitive adhesive layer
   33 Polarization film
   34 Second pressure sensitive adhesive layer
   35 Touch sensor film
   36 Third pressure sensitive adhesive layer
   37 Organic EL element
   38 Fourth pressure sensitive adhesive layer
   39 TFT substrate
S Test piece
P Holding plate

1. A pressure sensitive adhesive composition containing a multimer of modified cyclodextrin.

2. The pressure sensitive adhesive composition according to claim 1, wherein the multimer of modified cyclodextrin is a dimer.

3. A pressure sensitive adhesive obtained from the pressure sensitive adhesive composition according to claim 1.

4. The pressure sensitive adhesive according to claim 3, wherein it is an acrylic-based pressure sensitive adhesive.

5. The pressure sensitive adhesive according to claim 3, wherein it contains a crosslinked product obtained by crosslinking a (meth)acrylic ester polymer with a crosslinker.

6. The pressure sensitive adhesive according to claim 3, wherein its 100% modulus is 0.13 N/mm² or less.

7. The pressure sensitive adhesive according to claim 3, wherein its breaking stress in a tensile test is 0.25 N/mm² or more.

8. The pressure sensitive adhesive according to claim 3, wherein its breaking elongation in a tensile test is 650% or more.

9. The pressure sensitive adhesive according to claim 3, wherein it is a pressure sensitive adhesive for bonding an optical member and another optical member.

10. The pressure sensitive adhesive according to claim 3, wherein it is a pressure sensitive adhesive for bonding a bendable member and another bendable member that constitute a device that is repeatedly bent.

11. A pressure sensitive adhesive sheet having at least a pressure sensitive adhesive layer,
the pressure sensitive adhesive layer comprising the pressure sensitive adhesive according to claim 3.

12. The pressure sensitive adhesive sheet according to claim 11, wherein its adhesive strength to non-alkali glass is 1.0 N/25 mm or more and 50 N/25 mm or less.

13. The pressure sensitive adhesive sheet according to claim 11, wherein
the pressure sensitive adhesive sheet includes two release sheets, and
the pressure sensitive adhesive layer is interposed between the two release sheets so as to be in contact with release surfaces of the two release sheets.

14. A display body comprising:
a first display body structural member;
a second display body structural member; and
a pressure sensitive adhesive layer that bonds the first display body structural member and the second display body structural member to each other,
wherein the pressure sensitive adhesive layer is formed of the pressure sensitive adhesive according to claim 3.

15. A repetitive bending laminate member comprising:
a bendable member and another bendable member that constitute a device that is repeatedly bent; and
a pressure sensitive adhesive layer that bonds the bendable member and the other bendable member to each other,
wherein the pressure sensitive adhesive layer is formed of the pressure sensitive adhesive according to claim 3.

16. A repetitive bending device comprising the repetitive bending laminate member according to claim 15.
